(19) United States
(12) Patent Application Publication
(10) Pub. No.: US 2016/0013128 A1
(43) Pub. Date: Jan. 14, 2016

(54) SEMICONDUCTOR DEVICE AND MANUFACTURING METHOD THEREOF

(71) Applicant: KABUSHIKI KAISHA TOSHIBA, Minato-ku (JP)

(72) Inventors: Kenji AOYAMA, Yokkaichi (JP); Hideki Inokuma, Yokkaichi (JP); Kana Hirayama, Yokkaichi (JP)

(73) Assignee: KABUSHIKI KAISHA TOSHIBA, Minato-ku (JP)

(21) Appl. No.: 14/608,395

(22) Filed: Jan. 29, 2015

(30) Foreign Application Priority Data
Jul. 8, 2014 (JP) 2014-140952

(51) Int. Cl. H01L 23/528; H01L 23/532; H01L 23/522; H01L 21/768; H01L 21/285

(52) U.S. Cl. CPC H01L 23/528; H01L 21/76805; H01L 21/76877; H01L 21/76843; H01L 21/28518; H01L 21/28568; H01L 23/5226; H01L 23/53261; H01L 23/53266; H01L 23/53238; H01L 23/53271

(57) ABSTRACT

A method for manufacturing a semiconductor device includes forming a metal-containing layer over a semiconductor substrate, forming an insulating film to cover the semiconductor substrate and the metal-containing layer, forming a first contact hole that penetrates through the insulating film to reach the semiconductor substrate, forming a second contact hole that penetrates through the insulating film to reach the metal-containing layer, forming a first conductive plug on a portion, exposed through the first contact hole, of the semiconductor substrate and including a first material, forming a second conductive plug on the first conductive plug and including a second material, the semiconductor substrate being closer to a lower surface of the second conductive plug than to an upper surface of the metal-containing layer, and forming a third conductive plug on a portion, exposed through the second contact hole, of the metal-containing layer, the third conductive plug including a third material.

### CROSS-REFERENCE TO RELATED APPLICATION(S)

This application is based upon and claims the benefit of priority from Japanese Patent Application No. 2014-140952, filed on Jul. 8, 2014, the entire contents of which are incorporated herein by reference.

### FIELD

Embodiments described herein relate generally to a semiconductor device and a manufacturing method thereof.

### BACKGROUND

With increase in the degree of miniaturization of semiconductor devices, diameters of contact holes of contacts to semiconductor substrates and gate electrodes have been decreasing.

In recent years, contacts having a two-layer structure have come to be employed. In the two-layer structure, polysilicon which is superior in embeddability to metals is used as a filling material for filling a lower portion of a contact hole. Also, a metal is used as a filling material for filling an upper portion, located on the polysilicon-filled lower portion, of the contact hole.

### BRIEF DESCRIPTION OF THE DRAWINGS

FIGS. 1A and 1B show the electrical configuration of a semiconductor device according to a first embodiment of the invention;

FIGS. 2A to 2C are schematic sectional views of the semiconductor device according to the first embodiment;

FIGS. 3A to 3C are a first set of schematic sectional views illustrating a process for manufacturing the semiconductor device according to the first embodiment;

FIGS. 4A to 4C are a second set of schematic sectional views illustrating the process for manufacturing the semiconductor device according to the first embodiment;

FIGS. 5A to 5C are a third set of schematic sectional views illustrating the process for manufacturing the semiconductor device according to the first embodiment;

FIGS. 6A to 6C are a fourth set of schematic sectional views illustrating the process for manufacturing the semiconductor device according to the first embodiment;

FIGS. 7A to 7C are a fifth set of schematic sectional views illustrating the process for manufacturing the semiconductor device according to the first embodiment;

FIGS. 8A to 8C are a sixth set of schematic sectional views illustrating the process for manufacturing the semiconductor device according to the first embodiment;

FIGS. 9A to 9C are a seventh set of schematic sectional views illustrating the process for manufacturing the semiconductor device according to the first embodiment;

FIGS. 10A to 10C are an eighth set of schematic sectional views illustrating the process for manufacturing the semiconductor device according to the first embodiment;

FIGS. 11A to 11C are a ninth set of schematic sectional views illustrating the process for manufacturing the semiconductor device according to the first embodiment;

FIGS. 12A to 12C are a tenth set of schematic sectional views illustrating the process for manufacturing the semiconductor device according to the first embodiment;

FIGS. 13A to 13C are an eleventh set of schematic sectional views illustrating the process for manufacturing the semiconductor device according to the first embodiment;

FIGS. 14A to 14C are a twelfth set of schematic sectional views illustrating the process for manufacturing the semiconductor device according to the first embodiment;

FIGS. 15A to 15C are a thirteenth set of schematic sectional views illustrating the process for manufacturing the semiconductor device according to the first embodiment;

FIGS. 16A to 16C are schematic sectional views illustrating a process for manufacturing a semiconductor device according to a second embodiment of the invention;

FIGS. 17A to 17C are a first set of schematic sectional views illustrating a process for manufacturing a semiconductor device according to a third embodiment of the invention;

FIGS. 18A to 18C are a second set of schematic sectional views illustrating the process for manufacturing the semiconductor device according to the third embodiment; and

FIGS. 19A to 19C are schematic sectional views illustrating a process for manufacturing the semiconductor device according to a fourth embodiment of the invention.

### DESCRIPTION

Embodiments of the invention will be hereinafter described with reference to the accompanying drawings.

According to one embodiment of the invention, a method for manufacturing a semiconductor device, includes: forming a metal-containing layer over a semiconductor substrate; forming an insulating film so as to cover the semiconductor substrate and the metal-containing layer; forming a first contact hole that penetrates through the insulating film to reach the semiconductor substrate; forming a second contact hole that penetrates through the insulating film to reach the metal-containing layer; forming a first conductive plug on a portion, exposed through the first contact hole, of the semiconductor substrate, the first conductive plug including a first material; forming a second conductive plug on the first conductive plug, the second conductive plug including a second material different from the first material, the semiconductor substrate being closer to a lower surface of the second conductive plug than to an upper surface of the metal-containing layer; and forming a third conductive plug on a portion, exposed through the second contact hole, of the metal-containing layer, the third conductive plug including a third material.

### First Embodiment

A first embodiment which is directed to a bit line contact area of a NAND flash memory will be described below with reference to the accompanying drawings.

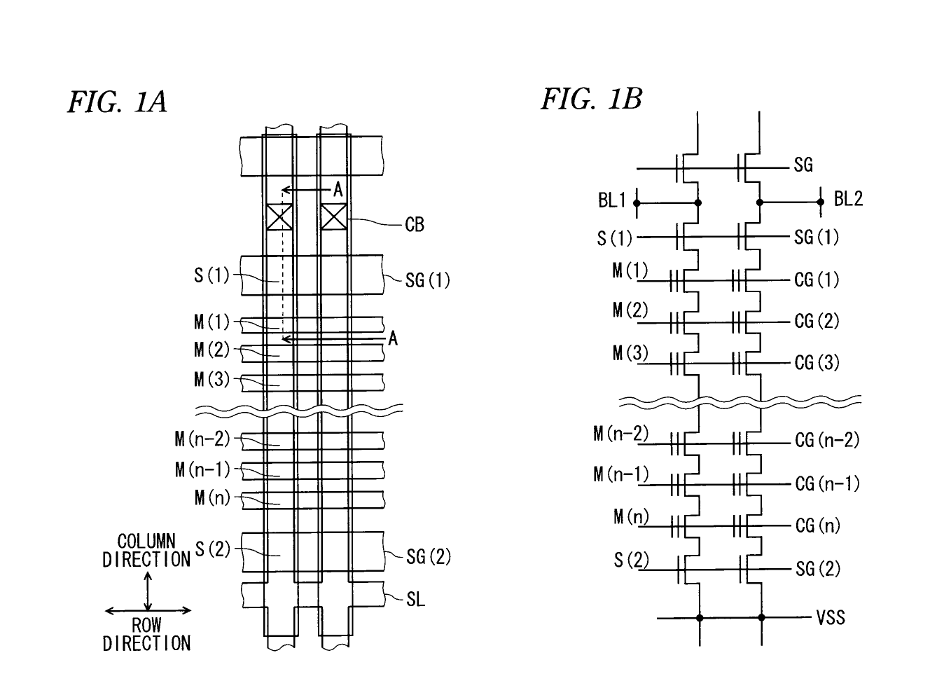

FIGS. 1A and 1B show an example of the configuration of the NAND flash memory. FIG. 1A is a plan view of memory cells of the NAND flash memory. FIG. 1B is an equivalent circuit diagram of the memory cells shown in FIG. 1A.

In FIGS. 1A and 1B, reference symbols M(1) to M(n) denote memory cell transistors; S(1) and S(2), selection transistors; CB, bit line contacts; CG(1) to CG(n), control gates (word lines); SG(1) and SG(2), selection gates; BL1 and BL2, bit lines; and SL, a source line.

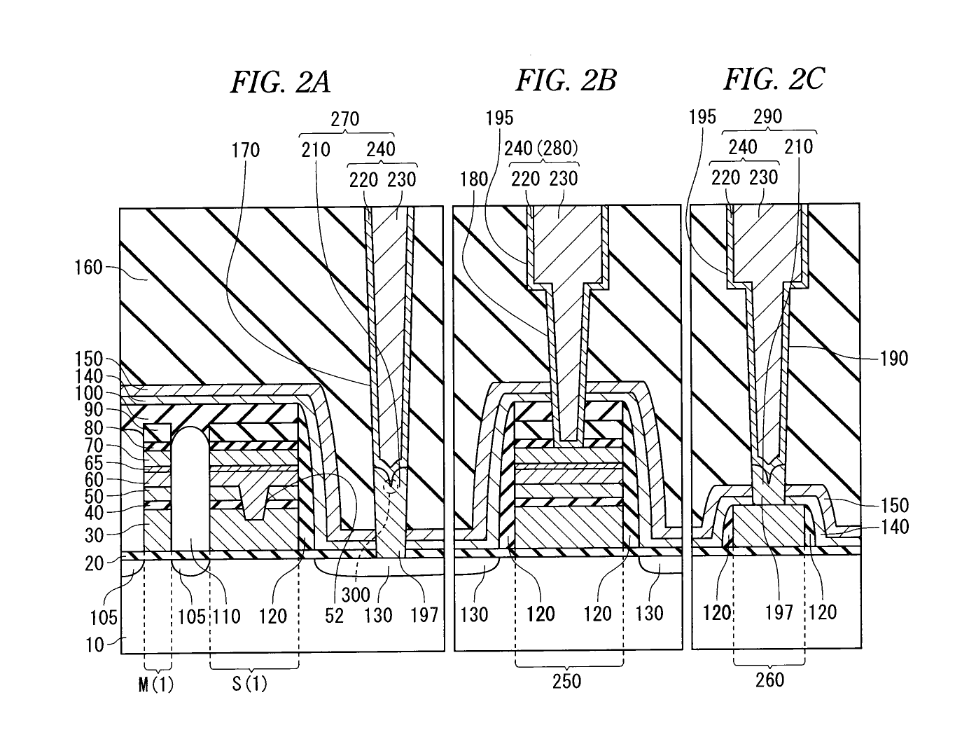

FIG. 2A is a schematic sectional view, taken along a line A-A in FIG. 1A, of the memory cell transistor M(1), the selection transistor S(1), and the bit line contact CB. FIG. 2B is a schematic sectional view of a region where a second contact 280 to a word line hook-up 250 is formed. FIG. 2C is a schematic sectional view of a region where a third contact 290 to a charge storage layer 30 of a circuit element 260 is formed.

In the following description, for the sake convenience, a semiconductor substrate side will be referred to as a “lower side.”

As shown in FIGS. 2A to 2C, plural first impurity diffusion layers 105 and plural second impurity diffusion layers 130 are formed in a surface of a p-type semiconductor substrate 10. An insulating film 20, the memory cell transistor M(1), the selection transistor S(1), the word line hook-up 250, the circuit element 260, and the like are formed on the surface of the semiconductor substrate 10. The word line hook-up 250 is a portion for electrically connecting a word line and an upper wiring layer via a contact.

The memory cell transistor M(1) includes a charge storage layer 30, a block film 40, a first control gate electrode layer 50, a second control gate electrode layer 60, a barrier metal layer 65, and a metal-containing layer 70. A first mask material layer 80 and a second mask material layer 90 are formed on the metal-containing layer 70. An insulating film 100 which is poor in coverage is formed on the second mask material layer 90. Because of the poor coverage of the insulating film 100, gaps 110 are formed between the memory cell transistor M(1) and the selection transistor S(1) and between the memory cell transistors M(1) and M(2). Data can be written into and read from the memory cell transistor M(1) by storing or releasing charge in or from the charge storage layer 30.

The selection transistor S(1) includes a slit portion 52 in addition to the similar configuration to the memory cell transistor M(1). The slit portion 52 is formed so as to penetrate through the first control gate electrode layer 50 and the block film 40. The second control gate electrode layer 60 is filled in the slit portion 52. As a result, in the selection transistor S(1), the metal-containing layer 70 is electrically connected to the charge storage layer 30. That is, the selection transistor S(1) can be used as what is called a transistor in which the metal-containing layer 70 and the insulating layer 20 serve as a gate electrode and a gate insulating film, respectively.

The word line hook-up 250 has approximately the same structure and films as the memory cell transistor M(1). In FIG. 2B, the word line hook-up 250 is formed on a p-well (not shown) that is formed in the semiconductor substrate 10. However, the word line hook-up 250 may be formed in a device isolation portion.

For example, the circuit element 260 is a resistance element or a capacitance element. More specifically, for example, the circuit element 260 is a resistance element that utilizes the resistance of the charge storage layer 30. Other specific examples of the circuit element 260 include (i) a capacitance element that uses a tunneling film 20 as a dielectric layer and uses the charge storage layer 30 and the semiconductor substrate 10 as electrodes and (ii) a capacitance element that uses the block film 40 as a dielectric layer and uses the charge storage layer 30 and the first control gate electrode 50 as electrodes.

Where the circuit element 260 is used as a capacitance element, a contact (not shown) is formed on a side of an electrode that is paired with the charge storage layer 30, that is, the semiconductor substrate 10, the first control gate electrode 50, or a conductor layer (for example, the second control gate electrode 60, the barrier metal layer 65, or the metal-containing layer 70) that is electrically connected to the first control gate electrode 50.

If necessary, spacers 120 may be formed in the memory cell transistor M(1), the selection transistor S(1), the word line hook-up 250, and the circuit element 260.

Furthermore, a silicon oxide film 140, a silicon nitride film 150, and an interlayer insulating film 160 are formed so as to cover the memory cell transistor M(1), the selection transistor S(1), the word line hook-up 250, the circuit element 260, and the semiconductor substrate 10.

Contact holes are formed to penetrate through the interlayer insulating film 160 from a conductive layer (e.g., aluminum metal layer; not shown) disposed on an upper side of the interlayer insulating film 160 to upper surfaces of the second impurity diffusion layer 130 adjacent to the selection transistor S(1), the metal-containing layer 70 of the word line hook-up 250, and the charge storage layer 30 of the circuit element 260. More specifically, a first contact hole 170 opens on the upper surface of the second impurity diffusion layer 130. A second contact hole 180 opens on the upper surface of the metal-containing layer 70 of the word line hook-up 250. A third contact hole 190 opens on the upper surface of the charge storage layer 30 of the circuit element 260. If necessary, upper portions of the first to third contact holes 170 to 190 may be formed with trenches 195 for formation of a wiring pattern.

First conductive plugs 210 are formed in lower portions of the first contact hole 170 and the third contact hole 190, respectively. Second conductive plugs 240 are formed above the first conductive plugs 210 and in the second contact hole 180. The semiconductor substrate 10 is closer to the lower surface of the second conductive plug 240 of the first contact 270 and a lower surface of a second conductive plug 240 of a third contacts 290 (which will be described later in detail) than to an upper surface of the metal-containing layer 70 of the word line hook-up 250. The expression “the semiconductor substrate 10 is closer to the lower surface of the second contact plug 240 than to the upper surface of the metal-containing layer 70 of the word line hook-up 250” means that the semiconductor substrate 10 is closer to a region 300 which is the closest to the semiconductor substrate 10 among regions on the lower surface of the second contact plug 240 than to the metal-containing layer 70. The region 300 may be a point, a line, or a surface.

A first contact 270 is formed in the first contact hole 170 by providing the first conductive plug 210 and the second conductive plug 240. The first contact 270 includes the first conductive plug 210 and the second conductive plug 240. A second contact 280 is formed in the second contact hole 180. The second contact 280 includes the second conductive plug 240. A third contact 290 is formed in the third contact hole 190. The third contact 290 includes the first conductive plug 210 and the second conductive plug 240.

Boundaries between the first conductive plugs 210 and the second conductive plugs 240 are located at a lower position than the upper surface of the metal-containing layer 70 of the word line hook-up 250.

The first conductive plugs 210 are disposed in the lower portions of the first contact hole 170 and the third contact hole 190, respectively. The first conductive plugs 210 are made of polysilicon which is superior in embeddability to metal films. This makes it possible to suppress resistance increase due to a filling failure. The term “filling failure” means formation of a void due to insufficient filling of a contact hole. A filling failure increases a contact resistance.

The second conductive plugs 240 can easily be buried in the first contact hole 170 and the third contact hole 190 because each of the second conductive plugs 240 in the first contact hole 170 and the third contact hole 190 can be formed by burying a metal film to a smaller depth than in a case of forming a contact plug by burying a metal film without the first conductive plug 210.

Each second conductive plug 240 includes a barrier metal layer 220 and a metal layer 230. Examples of a material of the barrier metal layer 220 include tantalum, titanium, niobium, tantalum nitride, titanium nitride, niobium nitride, tungsten nitride or a lamination film including films made of some of these materials. Examples of a material of the metal layer 230 include tungsten and aluminum. The second conductive plugs 240 are made of a metal material which is lower in electrical resistance than polysilicon. Therefore, contact resistances of the second conductive plugs 240 can be reduced to be lower than in a case where the contact holes 170 and 190 are filled with only polysilicon.

On the other hand, no first conductive plug 210 is provided in the second contact hole 180. That is, the second conductive plug 240 is in direct contact with the metal-containing layer 70 of the word line hook-up 250. This makes it possible to suppress occurrence of resistance increase due to a void failure.

The void failure will be described below.

If a first conductive plug 210 containing silicon were to be in contact with the metal-containing layer 70, silicon atoms contained in the first conductive plug 210 and metal atoms contained in the metal-containing layer 70 would undergo mutual diffusion to form a void due to thermal loads which are imposed in later processes. It is therefore desirable that in the second contact hole 180 for the word line hook-up 250, the second conductive plug 240 be formed on the metal-containing layer 70 without a first conductive plug 210 disposed therebetween.

In the second contact hole 180, the metal layer 230 is buried to a smaller depth than in the first contact hole 170 and the third contact hole 190. Therefore, occurrence of a filling failure as mentioned above is can be suppressed even without a first conductive plug 210.

Another example in which formation of a second conductive plug 240 on a first conductive plug 210 is proper as in this embodiment is a bit line contact of a NAND memory. This is because of the following reason. With regard to NAND memories, cost reduction can be achieved, for example, by reduction of the chip area. Also, the reduction of the chip area contributes to decrease in areas of bit line contacts existing in memory cells. However, if the area of the bit line contacts is decreased, it becomes difficult to embed the bit line contacts.

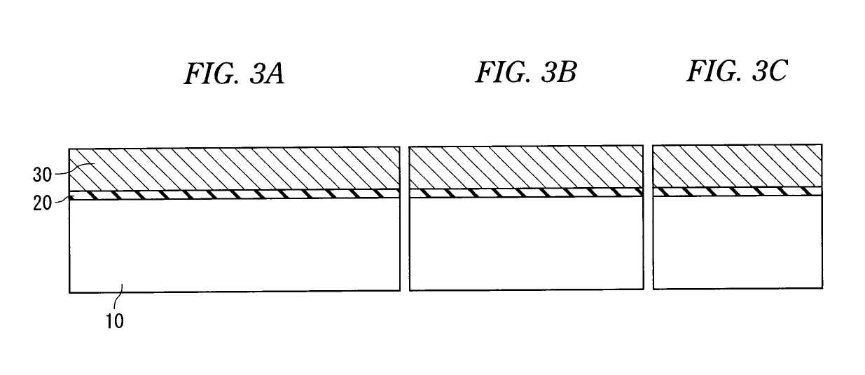

A method for manufacturing a semiconductor device according to this embodiment will be described below with reference to FIGS. 3A to 15C. Of FIGS. 3A to 15C, the drawings with the suffix “A” are sectional views taken along the line A-A in FIG. 1A (column direction), the drawings with the suffix “B” are sectional views of the region where the contact to the word line hook-up 250 is formed, and the drawings with the suffix “C” are sectional views of the region where the contact to the circuit element 260 having the charge storage layer 30 is formed.

First, p-type wells and n-type wells (not shown) are formed in the semiconductor substrate 10 by introducing impurities into the semiconductor substrate 10 by implantation.

As shown in FIGS. 3A to 3C, the insulating film 20 and the charge storage layer 30 are then formed on the semiconductor substrate 10. Examples of the insulating film 20 include a silicon oxide film, a silicon nitride film, a silicon oxynitride film, and a multilayer film of some of these films. Also, examples of the charge storage layer 30 include a polysilicon film, a metal film, an oxide film of polysilicon, an oxide film of a metal, a nitride film of polysilicon, a nitride film of a metal, and a lamination film of some of these films.

A silicon nitride film is formed on the charge storage layer 30. A resist pattern is formed on the silicon nitride film by lithography. The silicon nitride film is etched using the resist pattern as a mask. Then, the resist pattern is removed.

Using the resulting silicon nitride film as a mask, the charge storage layer 30, the insulating film 20, and the semiconductor substrate 10 are etched sequentially by RIE (reactive ion etching). As a result, stripe-shaped trenches (not shown) are formed in parallel to the column direction. Thereby, the charge storage layer 30 and the insulating film 20 are divided in the row direction.

Then, the trenches are filled with a silicon oxide film. Planarization is done by removing a portion of the silicon oxide film which is located above the silicon nitride film, by CMP (chemical mechanical polishing) using the silicon nitride film as a stopper film. The silicon nitride film is etched away using hot phosphoric acid. Next, the silicon oxide film is etched halfway using the charge storage layer 30 as a mask, whereby device isolation portions (not shown) are formed.

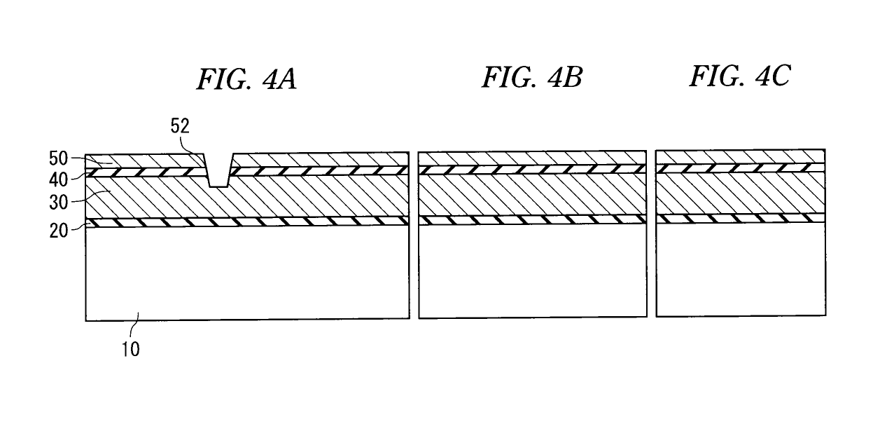

Subsequently, as shown in FIGS. 4A to 4C, the block film 40 and the first control gate electrode layer 50 are formed on the charge storage layer 30. A resist pattern is formed on the first control gate electrode layer 50 by lithography. The first control gate electrode layer 50, the block film 40, and the charge storage layer 30 are etched by RIE using the resist pattern as a mask, whereby slit portions 52 are formed. Then, the resist pattern is removed.

Examples of the block film 40 include a silicon oxide film, a silicon nitride film, a silicon oxynitride film, an aluminum oxide film, and a lamination layer of some of these films. Also, examples of the first control gate electrode layer 50 include a polysilicon layer, a metal silicide layer, a metal layer, and a lamination layer of some of these layers.

For example, the slit portions 52 are formed in regions where the selection gates SG(1) and SG(2) and/or peripheral circuit transistors are to be formed. It is desirable that the slit portions 52 do not reach the insulating film 20. Holes may be formed instead of the slit portions 52.

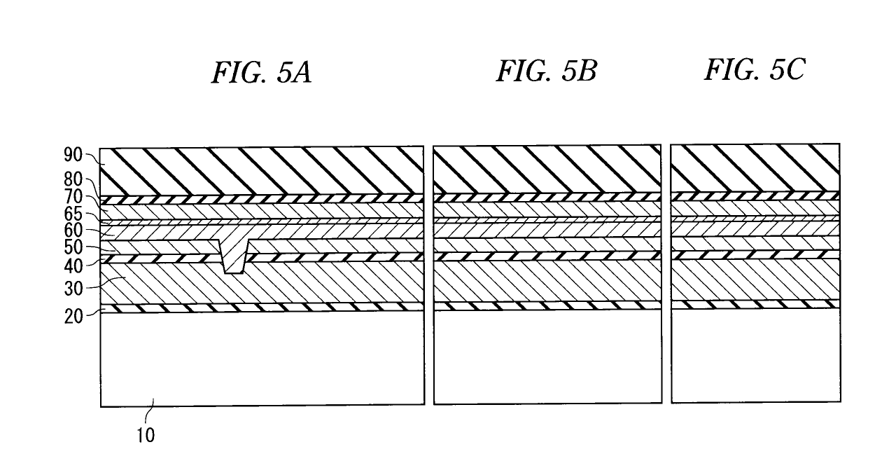

Subsequently, as shown in FIGS. 5A to 5C, the second control gate electrode layer 60, the barrier metal layer 65, and the metal-containing layer 70 are formed on the first control gate electrode layer 50.

The slit portion 52 electrically connects the metal-containing layer 70 to the charge storage layer 30. That is, each of the resulting transistors in which the slit portions 52 are formed is used as what is called a transistor in which the metal-containing layer 70 and the insulating film 20 are used as a gate electrode and a gate insulating film, respectively.

Examples of the second control gate electrode layer 60 include a polysilicon layer, a metal silicide layer, a metal layer, and a lamination layer of some of these layers. For example, the barrier metal layer 65 is made of titanium, tantalum, titanium nitride, tantalum nitride, or tungsten nitride. For example, the metal-containing layer 70 is made of metal silicide, tungsten, or copper.

Furthermore, as shown in FIGS. 5A to 5C, the first mask material layer 80 and the second mask material layer 90 are formed on the metal-containing layer 70. Examples of each of the first mask material layer 80 and the second mask material layer 90 include a silicon nitride film, a silicon oxide film, a polysilicon film, and a lamination film of some of these films.

Then, gate electrodes are formed by etching. A method in which gate electrodes of the memory cell transistors and gate electrodes of the selection transistors and the peripheral circuit transistors are formed separately by etching will be described below.

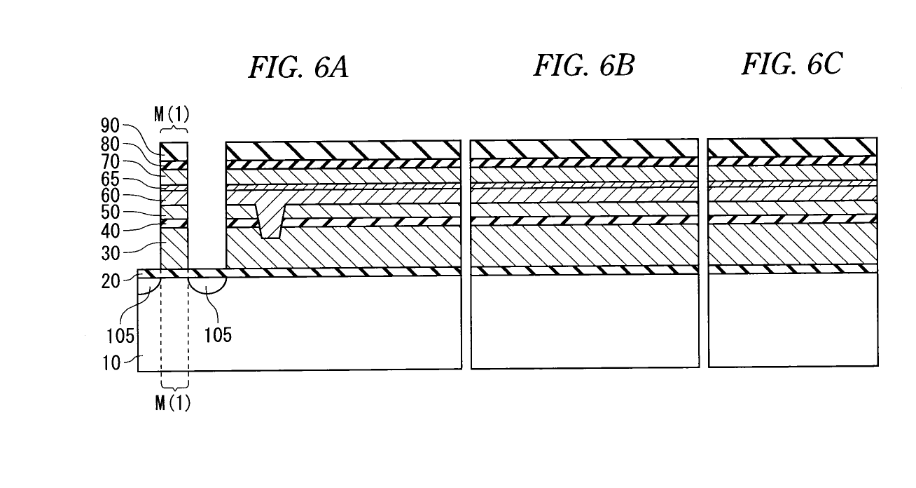

A mask pattern is formed on the second mask material layer 90 by lithography, etching, and the like. The first mask material layer 80 and the second mask material layer 90 are etched by RIE using this mask pattern as a mask. Furthermore, as shown in FIGS. 6A to 6C, the metal-containing layer 70, the barrier metal layer 65, the second control gate electrode layer 60, the first control gate electrode layer 50, the block film 40, and the charge storage layer 30 are etched using the thus-etched second mask material layer 90 as a mask. The insulating film 20 need not always be etched. Where the insulating film 20 is etched, it is desirable to stop its etching halfway. FIGS. 6A to 6C show a result of this step.

Resulting gate electrodes of the memory cells have a pattern of lines and spaces that are arranged in the column direction and extend in the row direction. The charge storage layer 30 is divided in the column direction and the row direction.

As shown in FIGS. 6A to 6C, then an impurity element is introduced by implantation, to thereby form first impurity diffusion layers 105 in source regions and drain regions of the memory cell transistors and the selection transistors.

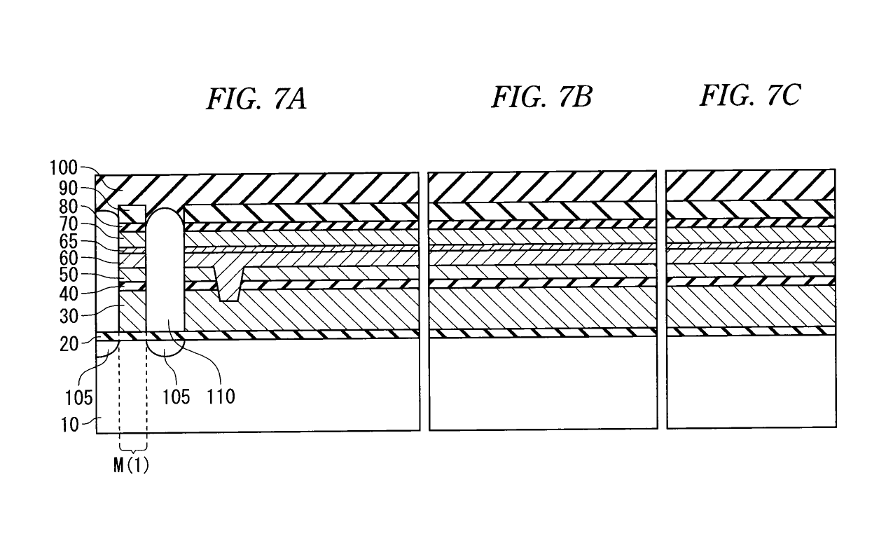

Subsequently, as shown in FIGS. 7A to 7C, an insulating film 100 which is poor in coverage is formed on the second mask material layer 90. Thereby, gaps 110 are formed between the memory cell transistors and between the end memory cell transistors and the selection transistors. Examples of the insulating film 100 include a silicon oxide film and a silicon nitride film which are formed by such a film forming method as sputtering or PECVD (plasma-enhanced chemical vapor deposition).

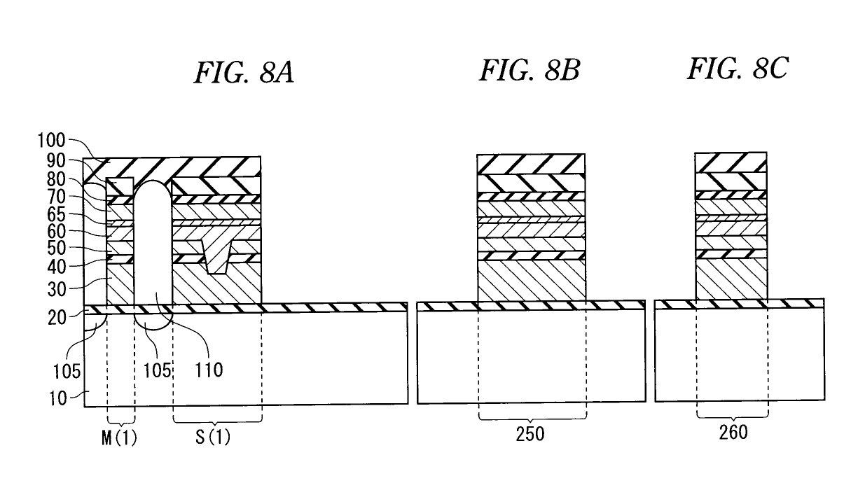

Then, a third mask material layer (not shown) is formed on the insulating film 100. A mask pattern is formed on the third mask material layer by lithography. The third mask material layer and the insulating film 100 are etched using this mask pattern as a mask. Furthermore, the second mask material layer 90, the first mask material layer 80, the metal-containing layer 70, the barrier metal layer 65, the second control gate electrode layer 60, the first control gate electrode layer 50, the block film 40, and the charge storage layer 30 are etched by RIE using the third mask material layer and the insulating film 100 as a mask. As a result, the selection transistor S(1), the word line hook-up 250, and the circuit element 60 are formed as shown in FIGS. 8A to 8C.

Examples of the third mask material layer include a silicon oxide film, a silicon nitride film, a polysilicon film, and a lamination film of some of these films. The state of FIGS. 8A to 8C is such that the third mask material layer has been etched away completely and the etching has proceeded to the insulating film 100. However, no problems arise even if a part of the third mask material layer remains. The insulating film 20 need not always be etched. Where the insulating film 20 is etched, it is desirable to stop its etching halfway.

If necessary, an impurity may be introduced by implantation to form, for example, LDD (lightly doped drain) structures.

Subsequently, the following process is executed to enable contact to the charge storage layer 30 of the circuit element 260.

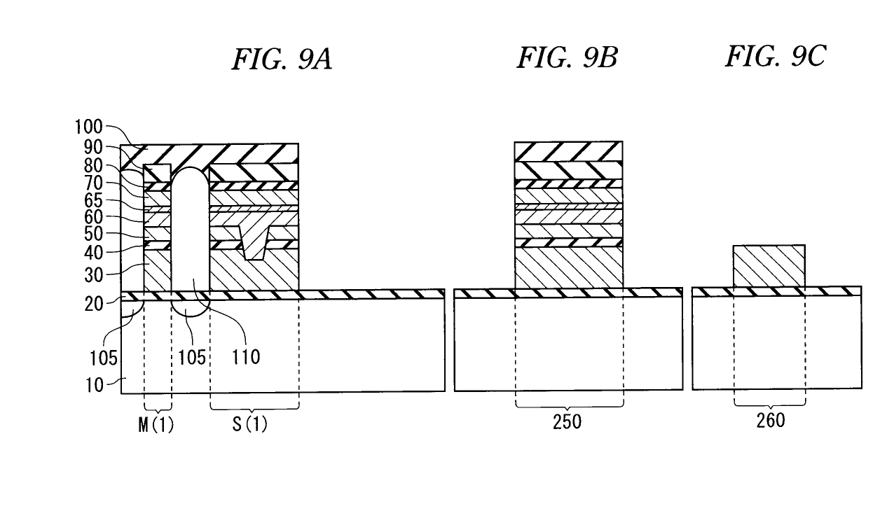

At first, a mask pattern is formed by lithography. As shown in FIGS. 9A to 9C, the insulating film 100, the second mask material layer 90, the first mask material layer 80, the metal-containing layer 70, the barrier metal layer 65, the second control gate electrode layer 60, the first control gate electrode layer 50, and the block film 40 are etched by RIE. In this manner, the films deposited on the charge storage layer 30 can be removed in a desired pattern (see FIGS. 9A to 9C). No problems arise even if the block film 40 of the circuit element 260 remains instead of being etched away.

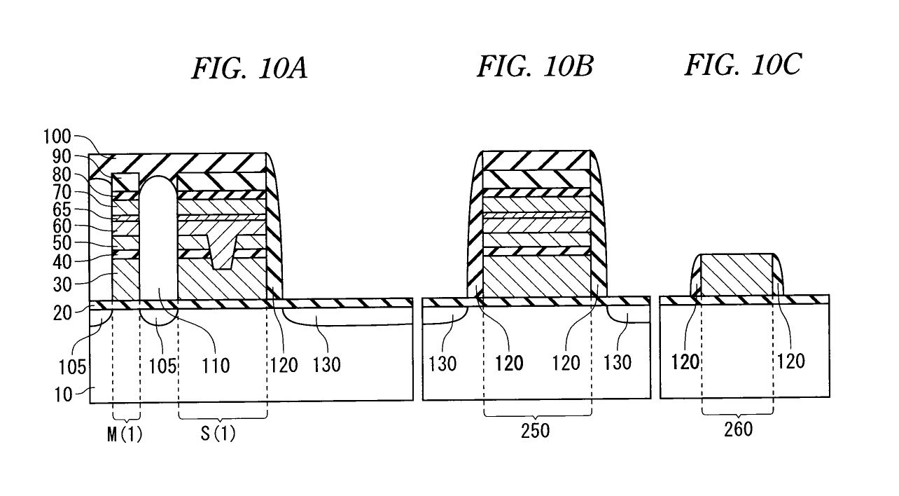

Subsequently, as shown in FIGS. 10A to 10C, a spacer film is formed and etched back by RIE. Thereby, spacers 120 are formed on the side wall surfaces of the transistors. Examples of each spacer 120 include a silicon oxide film, a silicon nitride film, and a lamination film thereof.

Furthermore, p-type impurity diffusion layers and n-type impurity diffusion layers are formed by introducing impurities by implantation. In FIGS. 10A to 10C, discrimination is not made between the p-type impurity diffusion layers and the n-type impurity diffusion layers; they are shown as second impurity diffusion layers 130. For example, boron or boron fluoride is used as an impurity for formation of the p-type impurity diffusion layers. Also, phosphorus or arsenic is used as an impurity for formation of the n-type impurity diffusion layers.

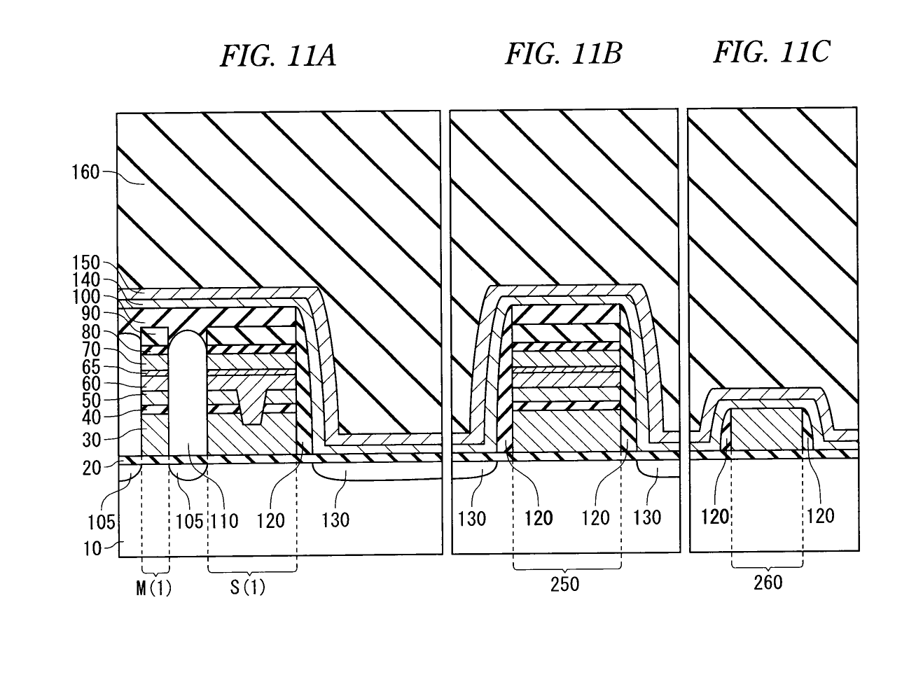

Next, the silicon oxide film 140 and the silicon nitride film 150 are formed so as to cover the semiconductor substrate 10, the memory cell transistors, and the like. Also, the interlayer insulating film 160 is formed on the silicon nitride film 150. For example, the interlayer insulating film 160 is a silicon oxide film. Since the memory cell transistors and the like have height differences with respect to the semiconductor substrate 10, the interlayer insulating film 160 also has a height variation. Therefore, the interlayer insulating film 160 is planarized by CMP to eliminate the height variation. and thereby facilitate subsequent formation of contact holes. A resulting state is shown in FIGS. 11A to 11C.

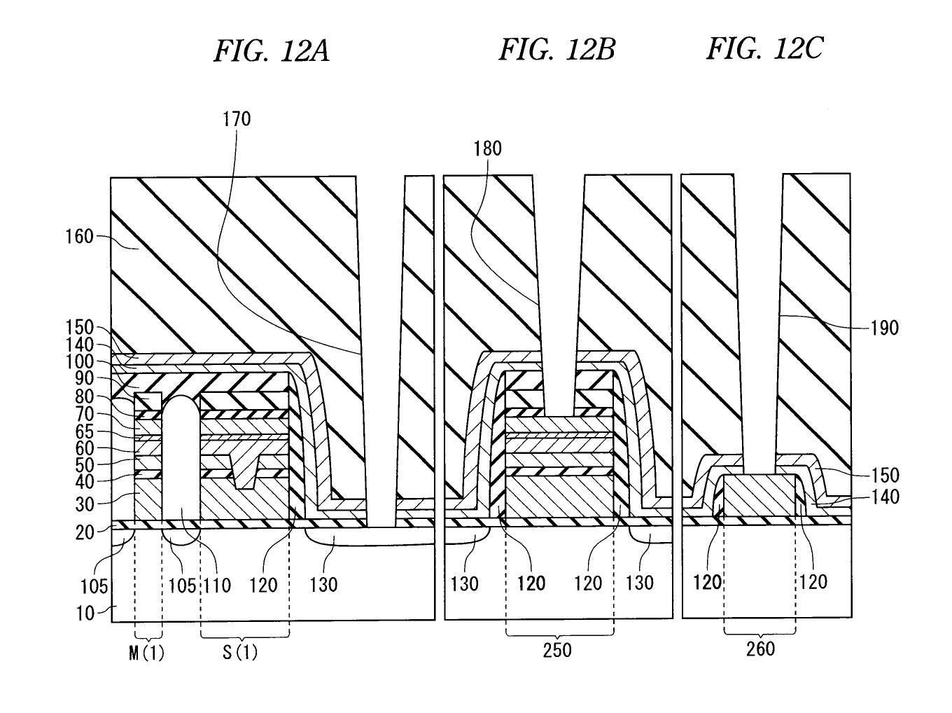

Then, a resist pattern is formed on the interlayer insulating film 160 by lithography. The first contact hole 170, the second contact hole 180, and the third contact hole 190 are formed using this resist pattern as a mask. The first contact hole 170 is formed so as to reach the second impurity diffusion layer 130. The second contact hole 180 is formed so as to reach the metal-containing layer 70 of the word line hook-up 250. The third contact hole 190 is formed so as to reach the charge storage layer 30 of the circuit element 260. A resulting state is shown in FIGS. 12A to 12C.

The above three kinds of contact holes may be formed by etching either simultaneously or separately (by two times or three times of etching). However, in terms of reduction of the manufacturing cost, it is desirable to form the contact holes simultaneously.

Then, a resist pattern is formed on the interlayer insulating film 160 by lithography. The interlayer insulating film 160 is etched by RIE using this resist pattern as a mask. Thereby, the trenches 195 for formation of a wiring pattern are formed.

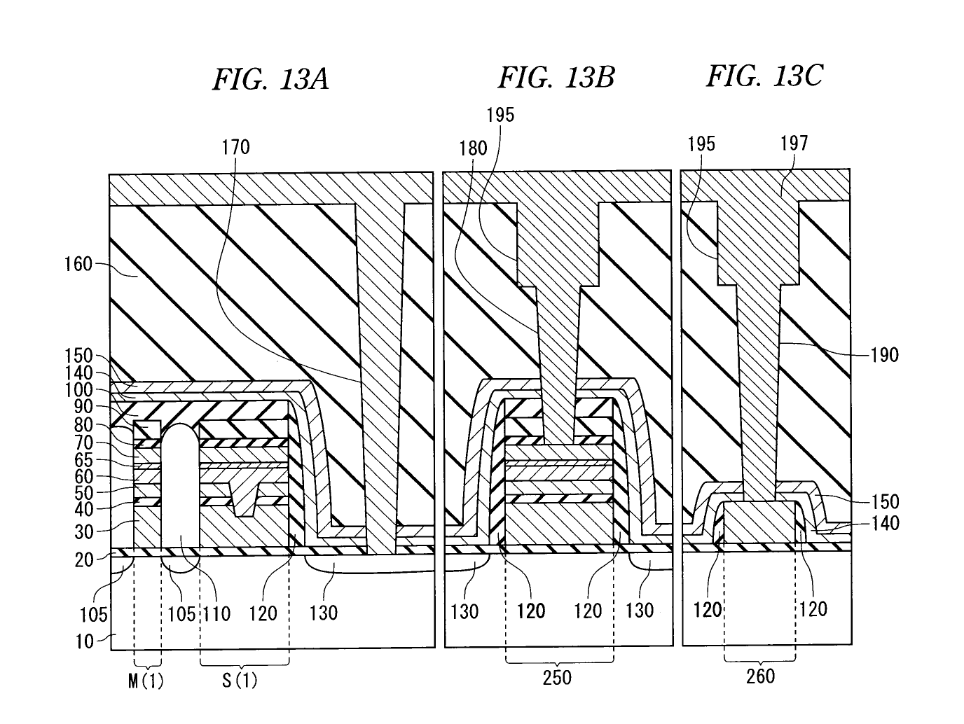

An amorphous silicon film 197 added with an impurity such as phosphorus or boron is formed by, for example, CVD (chemical vapor deposition) so as to fill lower portions of the contact holes 170, 180, and 190, respectively. Capable of being formed with better coverage than metal films, the silicon film 197 can be formed easily to bottom portions of the contact holes 170, 180, and 190. A resulting state is shown in FIGS. 13A to 13C.

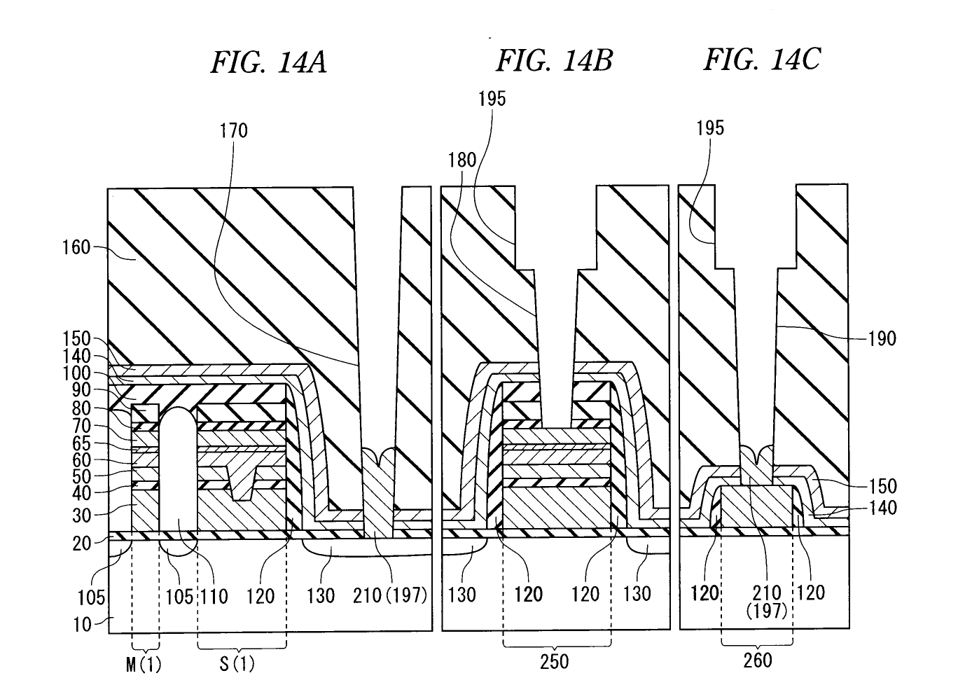

As shown in FIGS. 14A to 14C, the silicon films 197 are then etched back by RIE so that that portion of the silicon film 197 which is located in the second contact hole 180 and is in contact with the word line hook-up 250 is removed completely, whereas portions of the silicon films 197 remain in the first contact hole 170 and the third contact hole 190.

That is, the first conductive plugs 210 are formed by removing the portions of the silicon films 197, which are located inside the first contact hole 170 and the third contact hole 190, to positions to which the semiconductor substrate 10 is closer than to the upper end of the metal-containing layer 70 of the word line hook-up 250.

This etching is enabled by employing conditions that provide a large selection ratio for a silicon oxide film or a silicon nitride film. The selection ratio is the ratio of the etching rate of an etching subject material to that of an underlying material. In this embodiment, the selection ratio is the ratio of the etching rate of the silicon film 197 to that of the underlying interlayer insulating film 160 and metal-containing layer 70.

Subsequently, a resist pattern having an opening through which the first contact hole 170 above the p-type impurity diffusion layer 130 is exposed by lithography. An impurity is introduced by implantation using this resist pattern as a mask. The resist pattern is removed thereafter. If the silicon film 197 is added with an impurity of phosphorus, the impurity that is introduced by implantation in this step is boron, for example. As a result, the conductivity type of the silicon film 197 serving as the first conductive plug 210 formed in the first contact hole 170 that is formed on the p-type impurity diffusion layer 130 is changed to the p type.

Then, annealing is performed by RTA (rapid thermal annealing). The annealing renders the impurities, which were added at the time of the film formation and the implantation, be electrically active and also crystallizes the silicon films 197 into polysilicon.

Next, the barrier metal layer 220 and the metal layer 230 are formed so as to fill the inside of the contact holes 170, 180, and 190. Examples of the barrier metal layer 220 include tantalum, titanium, niobium, tantalum nitride, titanium nitride, niobium nitride, tungsten nitride and a lamination film of films made of some of these materials. For example, the metal layer 230 is made of tungsten or aluminum.

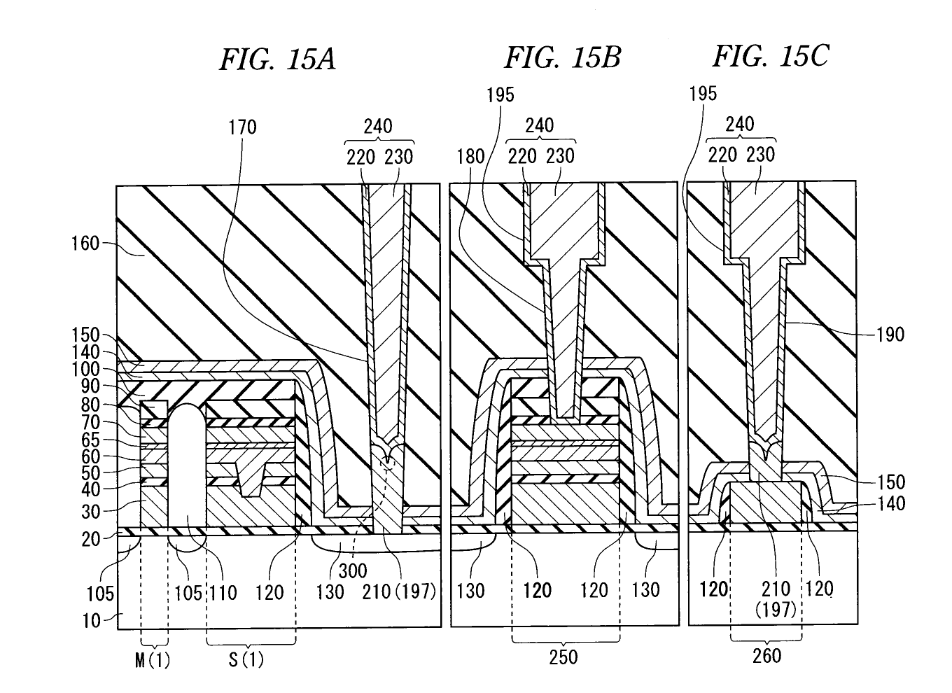

As shown in FIGS. 15A to 15C, those portions of the metal layer 230 and the barrier metal layer 220 which are formed on the interlayer insulating film 160 are then removed by CMP planarization. Thereby, the second conductive plugs 240 are completed. The semiconductor substrate 10 is closer to the lower surfaces of the second conductive plugs 240 of the first and third contacts 270, 290 than to the upper surface of the metal-containing layer 70 of the word line hook-up 250. The expression “the semiconductor substrate 10 is closer to the lower surface of the second contact plug 240 than to the upper surface of the metal-containing layer 70 of the word line hook-up 250” means that the semiconductor substrate 10 is closer to a region 300 which is the closest to the semiconductor substrate 10 among regions on the lower surface of the second contact plug 240 than to the metal-containing layer 70. The region 300 may be a point, a line, or a surface.

In this embodiment, the silicon film 197 in the second contact hole 180 is removed. This makes it possible to reduce mutual diffusion of silicon atoms and metal atoms contained in the metal-containing layer 70 due to thermal loads imposed in later processes, which results in suppression of occurrence of a void. That is, increase of the contact resistance can be suppressed.

With the above-described introduction of the impurity by implantation, the first conductive plug 210 made of the n-type silicon film 197 is formed on the n-type impurity diffusion layer 130, and the first conductive plug 210 which is made of the p-type silicon film 197 is formed on the p-type impurity diffusion layer 130. This prevents formation of a pn junction between the second impurity diffusion layer 130 and the adjacent first conductive plug 210.

In this embodiment, the region where the contact to the bit line contact CB is formed and the region where the contact to the word line hook-up 250 is formed are described. However, any combination of a contact to a semiconductor substrate and a contact to a metal-containing layer formed over the semiconductor substrate can provides the same advantage as this embodiment. For example, instead of the contact to the word line hook-up 250, the concept of this embodiment is applicable to a contact to a selection gate line hook-up and a contact to a transistor of a peripheral circuit which is not the memory cell.

Also, the etch-back processing on the silicon film 197 may be controlled by detecting a variation of the intensity of light emitted from active species and ions in plasma that is used by RIE. More specifically, the etch-back processing on the silicon film 197 formed in the first contact hole 170, the second contact hole 180, and the third contact hole 190 is controlled by detecting a time point at which the removal of the silicon film 197 located above the interlayer insulating film 160 is completed.

A light intensity variation is detected by the following method. When the silicon film 197 located above the interlayer insulating film 160 has been removed completely, the surface area of the silicon film 197 that is exposed to the plasma decreases. Since the surface area of the silicon film 197 (etching subject film) decreases, the densities of active species and ions in the plasma that is used by RIE vary. As a result, a light intensity varies. This light intensity variation is detected.

This control method in which a light intensity variation is detected makes it possible to control the etch-back processing better than the control method which time-controls the etch-back processing itself on the silicon film 197.

More specifically, this control method makes it easier to solve the followings. For example, if the etching time is too long, those portions of the silicon film 197 which should remain in the first contact hole 170 and the third contact hole 190 might be also removed, which means that first conductive plugs 210 are not formed. Conversely, if the etching time is too short, the silicon film 197 in the second contact hole 180 might not be removed completely. These cases can be solved easily by controlling the etch-back processing more properly.

### Second Embodiment

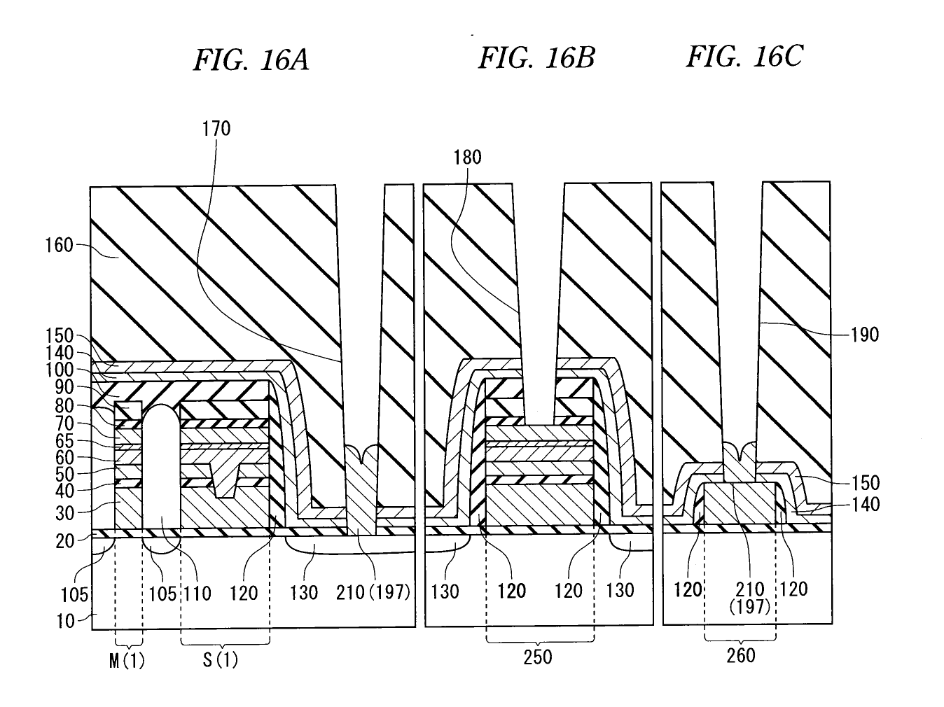

A second embodiment of the invention will be described below. The procedure to be followed until formation of the first contact hole 170, the second contact hole 180, and the third contact hole 190 (FIGS. 12A to 12C) is the same as the first embodiment. Hence, description thereon will be omitted below. As in the description of the first embodiment, FIG. 16A is a sectional view taken along the line A-A in FIG. 1A (column direction), FIG. 16B is a sectional view of a region where a contact to a word line hook-up 250 is formed, and FIG. 16C is a sectional view of a region where a contact to a circuit element 260 having the charge storage layer 30 is formed.

In the first embodiment, the trenches 195 for formation of the wiring pattern are formed in this state (see FIGS. 13A to 13C). On the other hand, in the second embodiment, the first conductive plugs 210 are formed first. That is, as shown in FIGS. 16A to 16C, the first conductive plugs 210 are formed first by forming an amorphous silicon film 197 and etching back the amorphous silicon film 197 by RIE.

Then, trenches 195 for formation of a wiring pattern are formed by photolithography and RIE (see FIGS. 14A to 14C). The procedure to be followed thereafter is the same as in the first embodiment and hence will not be described below.

Unlike in the first embodiment, this manufacturing method does not form a silicon film 197 in the trenches 195 for formation of a wiring pattern. Therefore, the second embodiment is advantageous in that residues of the silicon film 197 which is etched back by RIE are not likely left in the trenches 195 for formation of a wiring pattern, which means an advantage that second conductive plugs 240 can be formed later more easily.

### Third Embodiment

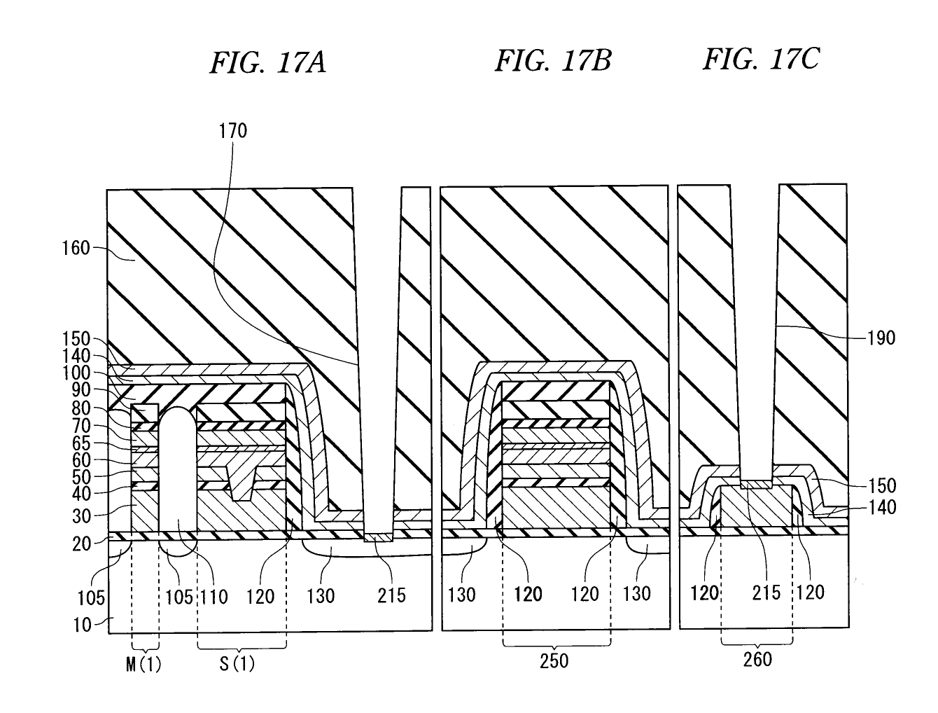

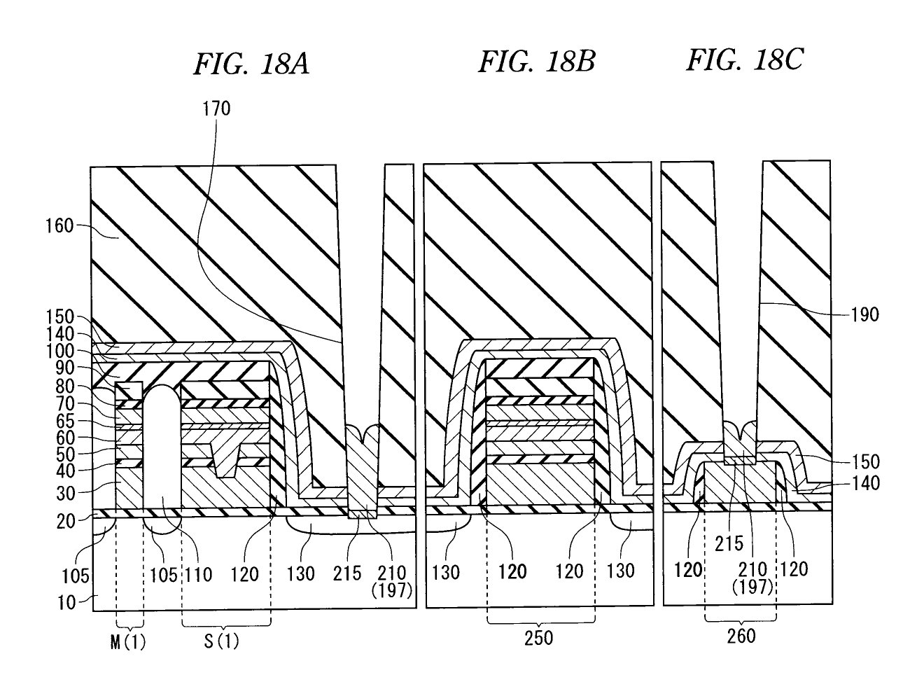

A third embodiment of the invention will be described below. As in the description of the first embodiment, in FIGS. 17A to 18C, the drawings with the suffix “A” are sectional views taken along the line A-A in FIG. 1A (column direction), the drawings with the suffix “B” are sectional views of a region where a contact to the word line hook-up 250 is formed, and the drawings with the suffix “C” are sectional views of a region where a contact to the circuit element 260 having the charge storage layer 30 is formed. In this embodiment, as shown in FIGS. 17A to 17C, the first contact hole 170 and the third contact hole 190 are formed first.

Subsequently, metal films made of cobalt, titanium, tantalum, tungsten, or the like are formed, and annealing is performed by RTA. As a result, metal silicide layers 215 are formed in a portion, in a lower portion of the first contact hole 170, of the semiconductor substrate 10 and a portion, in a bottom portion of the third contact hole 190, of the charge storage layer 30. Residual metal films are thereafter removed by a mixed liquid of sulfuric acid and hydrogen peroxide.

Subsequently, as shown in FIGS. 18A to 18C, the first conductive plugs 210 are formed in the lower portions of the first and third contact holes 170, 190, respectively. The method for forming the first conductive plugs 210 may be the same as in the second embodiment.

Then, the second contact hole 180 is formed. The procedure to be followed thereafter is the same as in the second embodiment. Hence, the description thereon will be omitted below.

According to this embodiment, the metal silicide layers 215 enable further reduction of the contact resistances between (i) the first conductive plugs 210 and (ii) the second impurity diffusion layer 130 or the charge storage layer 30. Furthermore, the lower portion of the second contact hole 180 is not exposed to plasma that is used in etching for formation of the first conductive plugs 210. As such, the third embodiment provides an advantage that the insulating film 20 and the block film 40 of the memory cell transistors connected to the word line hook-up 250 on which the second contact hole 180 opens do not suffer plasma damage.

### Fourth Embodiment

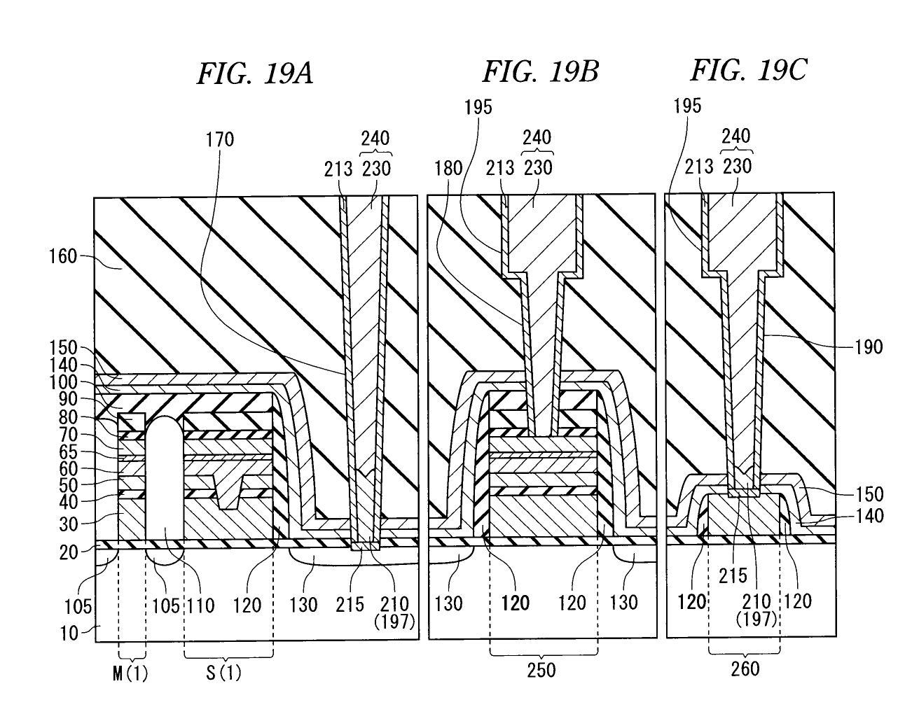

A fourth embodiment of the invention will be described below. As in the description of the first embodiment, FIG. 19A is a sectional view taken along the line A-A in FIG. 1A (column direction), FIG. 19B is a sectional view of a region where a contact to the word line hook-up 250 is formed, and FIG. 19C is a sectional view of a region where a contact to the circuit element 260 having the charge storage layer 30 is formed. The procedure to be followed until formation of trenches 195 for formation of a wiring pattern (see FIGS. 13A to 13C) is the same as in the first embodiment. Hence, the description thereon will be omitted below.

A metal film 213 is then formed. Examples of the metal film 213 include titanium, tantalum, titanium nitride, tantalum nitride and a lamination film of films made of some of these materials. Then metal silicide layers 215 are formed by RTA annealing in the same manner as in the third embodiment.

Subsequently, as shown in FIGS. 19A to 19C, a silicon film 197 is formed with the metal film 213 left as it is. Then, the silicon film 197 is etched back.

Next, a metal film 230 is formed and flattened by CMP. Thereby, the second conductive plugs 240 are formed. In this embodiment, barrier metal layers 220 need not be formed because the metal films 213 function as barrier metal layers.

According to this embodiment, as in the third embodiment, the metal silicide layers 215 enable further reduction of the contact resistances between (i) the first conductive plugs 210 and (ii) the second impurity diffusion layer 130 or the charge storage layer 30. Furthermore, the first contact hole 170, the second contact hole 180, and the third contact hole 190 can be formed simultaneously. As a result, the number of manufacturing steps is decreased and hence the manufacturing cost can be reduced.

In the example of FIGS. 19A to 19C, those portions of the metal layer 213 which are located on the interlayer insulating film 160 or constitute the lower flat portion of the second contact hole 180 are etched away. If the metal layer 213 is sufficiently thin as compared with the etching rate of the silicon film 197, as in the above example the portion of the metal layer 213 in the second contact hole 180 is etched away. However, there are no problems even if a portion of the second contact hole 180 remains on the interlayer insulating film 160 or at the lower portion of the second contact hole 180.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, the method comprising:
forming a metal-containing layer over a semiconductor substrate;
forming an insulating film so as to cover the semiconductor substrate and the metal-containing layer;
forming a first contact hole that penetrates through the insulating film to reach the semiconductor substrate;
forming a second contact hole that penetrates through the insulating film to reach the metal-containing layer;
forming a first conductive plug on a portion, exposed through the first contact hole, of the semiconductor substrate, the first conductive plug including a first material;
forming a second conductive plug on the first conductive plug, the second conductive plug including a second material different from the first material, the semiconductor substrate being closer to a lower surface of the second conductive plug than to an upper surface of the metal-containing layer; and
forming a third conductive plug on a portion, exposed through the second contact hole, of the metal-containing layer, the third conductive plug including a third material.

2. The method of claim 1, wherein
the forming the first contact hole includes substantially the same process as the forming the second contact hole includes.

3. The method of claim 1, wherein
the forming the second conductive plug includes substantially the same process as the forming the third conductive plug includes.

4. The method of claim 1, wherein
the forming the first contact hole includes substantially the same process as the forming the second contact hole includes; and
the forming the second conductive plug includes substantially the same process as the forming the third conductive plug includes.

5. The method of claim 1, wherein
the second material is the same as the third material.

6. The method of claim 5, wherein
the metal-containing layer includes at least one of metal silicide, tungsten, and copper,
the first material is silicon, and
the second material is tungsten.

7. The method of claim 1, wherein
the metal-containing layer includes at least one of metal silicide, tungsten, and copper,
the forming the first conductive plug includes
forming an amorphous silicon film, and
thereafter etching the amorphous silicon film to a position where an upper surface of the amorphous silicon film is lower than the upper surface of the metal-containing layer, and
the forming the second conductive plug includes
forming a barrier metal layer including titanium, titanium nitride, or a lamination film of respective films made of titanium and titanium nitride, and
thereafter forming a metal layer having tungsten.

8. The method of claim 7, wherein
the forming the first contact hole includes substantially the same process as the forming the second contact hole includes; and
the forming the second conductive plug includes substantially the same process as the forming the third conductive plug includes.

9. The method of claim 1, further comprising:
after the forming the first conductive plug and before the forming the second conductive plug, introducing at least one of boron, phosphorus, and arsenic by implantation into the first conductive plug.

10. The method of claim 1, further comprising:
after the forming the second contact hole and before the forming the first conductive plug, forming a trench having a wiring pattern shape in an upper portion of at least one of the first contact hole and the second contact hole.

11. The method of claim 1, further comprising:
after the forming the first contact hole and before the forming the first conductive plug, forming a metal silicide layer at a lower portion of the first contact hole.

12. A semiconductor device comprising:
a semiconductor substrate;
an impurity diffusion layer provided in the semiconductor substrate;
a metal-containing layer provided above the semiconductor substrate;
an insulating film configured to cover the semiconductor substrate and the metal-containing layer;
a first contact hole configured to penetrate through the insulating film to reach the impurity diffusion layer;
a first conductive plug provided in a lower portion of the first contact hole, the first conductive plug containing a first material;
a second conductive plug provided above the first conductive plug in the first contact hole, the second conductive plug having a lower surface, the semiconductor substrate being closer to the lower surface of the second conductive plug than to an upper surface of the metal-containing layer, the second conductive plug containing a second material different from the first material;
a second contact hole configured to penetrate through the insulating film to reach the metal-containing layer; and
a third conductive plug provided in the second contact hole, the third conductive plug containing a third material.

13. The semiconductor device of claim 12 wherein
the second material is the same as the third material.

14. The semiconductor device of claim 13, wherein
the first material is silicon, and
the second material and the third material are tungsten.

15. The semiconductor device of claim 12, wherein
the second conductive plug includes
a first barrier metal layer including at least one of titanium and titanium nitride, and
a first metal layer including tungsten, and
the third conductive plug includes
a second barrier metal layer including at least one of titanium and titanium nitride, and
a second metal layer including tungsten.

16. The semiconductor device of claim 15, wherein
the metal-containing layer includes at least one of metal silicide, tungsten, and copper,
the first conductive plug includes silicon;

[symbol]

17. The semiconductor device of claim 16, wherein
the first conductive plug including at least one of boron, phosphorus and arsenic.

18. The semiconductor device of claim 16, further comprising:
a metal silicide layer provided between the first conductive plug and the semiconductor substrate.
